(19) United States
(12) Patent Application Publication
(10) Pub. No.: US 2025/0040282 A1
(43) Pub. Date: Jan. 30, 2025

(54) IMAGE SENSORS AND METHODS OF FABRICATING THE SAME

(71) Applicant: Samsung Electronics Co., Ltd., Suwon-si (KR)

(72) Inventors: Jihun LIM, Suwon-si (KR); Sungki MIN, Suwon-si (KR); Chang Kyu LEE, Suwon-si (KR); Yongkun JO, Suwon-si (KR)

(21) Appl. No.: 18/628,099

(22) Filed: Apr. 5, 2024

(30) Foreign Application Priority Data
Jul. 28, 2023 (KR) 10-2023-0099220

(51) Int. Cl. H01L 27/146

(52) U.S. Cl. CPC H01L 27/14636; H01L 27/14643; H01L 27/14683

(57) ABSTRACT

An image sensor includes a substrate region having a photoelectric conversion region and a floating diffusion region therein. The floating diffusion region is configured to receive charges generated in the photoelectric conversion region in response to light incident the photoelectric conversion region. First and second horizontal conductive lines are provided that extend on the substrate region, but at different heights relative to a surface of the substrate region. The first horizontal conductive line is electrically connected to the floating diffusion region and has a thickness smaller than a thickness of the second horizontal conductive line. In addition, the first horizontal conductive line extends closer to the substrate region than the second horizontal conductive line.

### REFERENCE TO PRIORITY APPLICATION

This application priority under 35 U.S.C. § 119 to Korean Patent Application No. 10-2023-0099220, filed Jul. 28, 2023, the disclosure of which is hereby incorporated herein by reference.

### BACKGROUND

The present disclosure relates to image sensors and methods of fabricating image sensors.

Image sensors are devices that convert optical image signals into electrical signals, and include charge coupled device (CCD) image sensors and complementary metal oxide semiconductor (CMOS) image sensors, for example. The image sensor includes a plurality of pixels. Each pixel includes a light-receiving area that receives incident light and converts it into an electrical signal, and a pixel circuit that outputs a pixel signal using charges generated in the light-receiving area.

Recently, as the integration of image sensors has increased, the size of each pixel has generally become smaller. Unfortunately, there is an ongoing problem because image transmission delays depend on the arrangement and shape of components in the pixel, and can deteriorate the quality of image sensors having higher integration density.

### SUMMARY

Embodiments of the present disclosure provide an image sensor with reduced capacitance between conductive lines, which do not transmit high-speed signals, and other conductive lines, which may transmit high-speed signals, and methods of fabricating the same.

Embodiments of the present disclosure provide an image sensor with improved high-speed signal transmission characteristics of a high-speed signal transmission conductive line, and methods of fabricating the same.

According to an embodiment, an image sensor includes: a substrate region having therein a photoelectric conversion region and a floating diffusion region, which receives charges generated in the photoelectric conversion region, a first horizontal conductive line extending on the substrate region, and a second horizontal conductive line extending on the substrate region. The first horizontal conductive line is electrically connected to the floating diffusion region. The first horizontal conductive line and the second horizontal conductive line are located at different heights. The first horizontal conductive line has a thickness smaller than the second horizontal conductive line.

According to another embodiment, a method of fabricating an image sensor includes: forming a device layer including (i) a substrate region having therein a photoelectric conversion region and a floating diffusion region, which receives charges generated in the photoelectric conversion region, (ii) an upper insulating layer provided on the substrate region, and (iii) a first contact penetrating the upper insulating layer and electrically connected to the floating diffusion region. The method also includes: sequentially forming a first capping layer and a first interlayer insulating layer on the upper insulating layer, forming a first trench exposing the first contact by etching the first interlayer insulating layer and the first capping layer, forming a second interlayer insulating layer on the upper insulating layer, and forming a second trench by etching the second interlayer insulating layer. A first depth of the first trench is shallower than a second depth of the second trench; and the first trench and the second trench are formed at different heights.

According to a further embodiment, an image sensor includes a substrate region having a photoelectric conversion region and a floating diffusion region therein. The floating diffusion region is configured to receive charges generated in the photoelectric conversion region in response to light incident the photoelectric conversion region. First and second horizontal conductive lines are also provided; these conductive lines extend on the substrate region, but at different heights relative to a surface of the substrate region. In some embodiments, the first horizontal conductive line is electrically connected to the floating diffusion region and has a thickness smaller than a thickness of the second horizontal conductive line. In some embodiments, the first horizontal conductive line extends closer to the substrate region than the second horizontal conductive line. In some embodiments, the image sensor may also include a source follower transistor, which extends on the substrate region and has a gate terminal electrically connected to the first horizontal conductive line. In some embodiments, the image sensor may also include a reset transistor, which extends on the substrate region and has a drain terminal electrically connected to the first horizontal conductive line. In some embodiments, a first thickness of the first horizontal conductive line may be less than half a second thickness of the second horizontal conductive line.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensor according to an exemplary embodiment.

FIG. 2 is a plan layout view of the pixel array of FIG. 1.

FIG. 3 is an equivalent circuit diagram of the pixel group of FIG. 1.

FIG. 4A represents a plan view of an image sensor according to exemplary embodiments.

FIG. 4B is a cross-sectional view along line A-A′ of FIG. 4A.

FIG. 4C is a cross-sectional view along line B-B′ of FIG. 4A.

FIGS. 5 to 11 correspond to line A-A′ in FIG. 4A and describe the manufacturing methods of an image sensor according to exemplary embodiments.

FIG. 12 is a cross-sectional view corresponding to the A-A′ line of FIG. 4A, representing an image sensor according to exemplary embodiments.

FIG. 13 is a cross-sectional view corresponding to line A-A′ of FIG. 4A, representing an image sensor according to exemplary embodiments.

FIG. 14 is a cross-sectional view corresponding to line A-A′ of FIG. 4A, representing an image sensor according to exemplary embodiments.

### DETAILED DESCRIPTION OF EMBODIMENTS

Hereinafter, examples for carrying out the present invention will be clearly and specifically described so that one having ordinary skill in the technical field of the present invention may readily practice the invention.

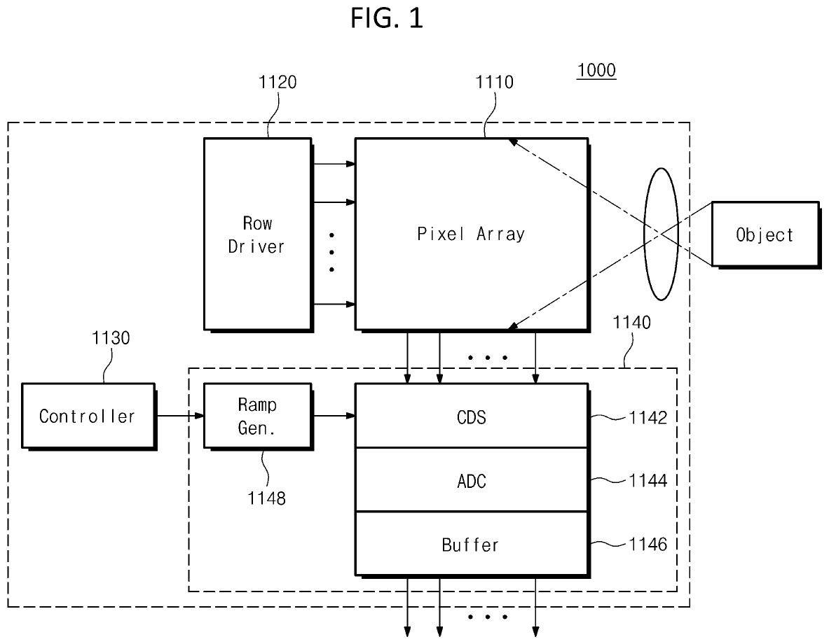

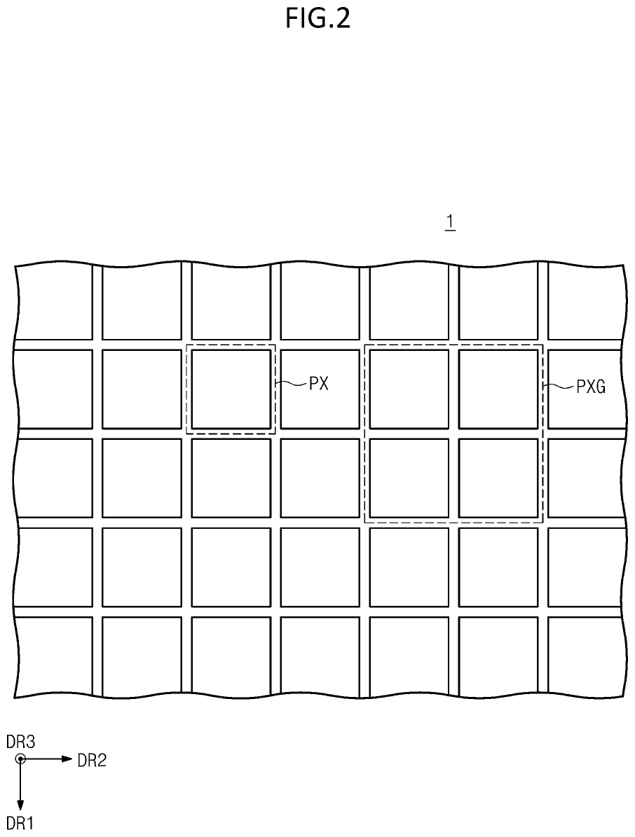

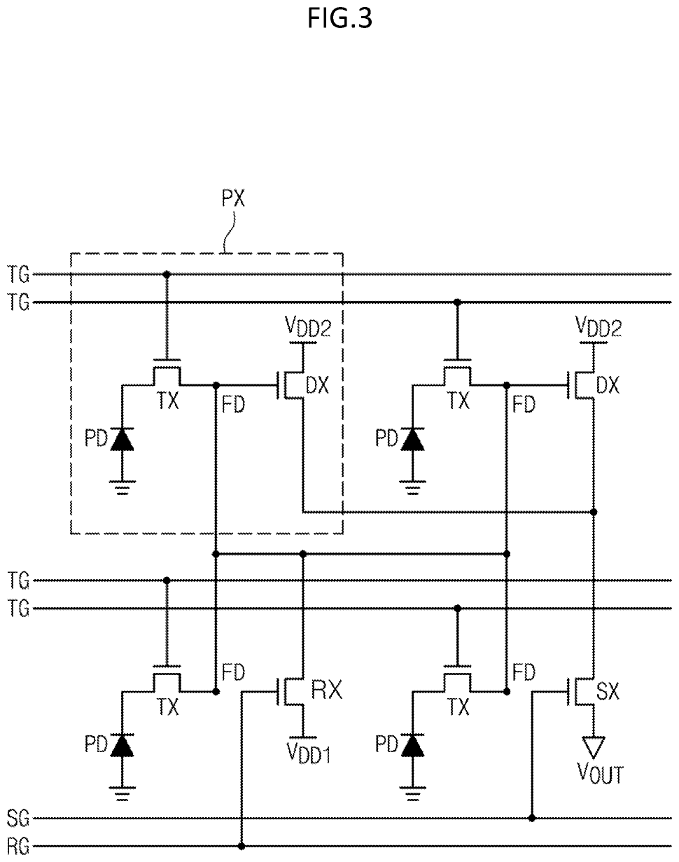

FIG. 1 is a block diagram of an image sensor according to an exemplary embodiment; FIG. 2 is a plan view of the pixel array of FIG. 1; and FIG. 3 is an equivalent circuit diagram of the pixel group of FIG. 1. Referring to FIG. 1, an image sensor 1000 may be provided. The image sensor 1000 may be mounted on an electronic device having an image or light sensing function. For example, the image sensor 1000 may be mounted on electronic devices such as a camera, smartphone, wearable device, Internet of Things (IoT), tablet PC (Personal Computer), PDA (Personal Digital Assistant), PMP (Portable Multimedia Player), navigation device, etc. The image sensor 1000 may also be mounted on electronic devices that are installed as components in vehicles, furniture, manufacturing equipment, doors, various measuring instruments, etc. The image sensor 1000 may include a control section comprising a pixel array 1110, a controller 1130, a row driver 1120, and a pixel signal processing unit 1140.

As shown in FIG. 2, the pixel array 1110 may include a plurality of pixels arranged two-dimensionally along a first direction DR1 and a second direction DR2. The plurality of pixels may be arranged in a specific pattern to generate high-quality images. For example, the plurality of pixels may be arranged in a Bayer pattern or chess mosaic pattern. When the pixels have a Bayer pattern, each pixel in the pixel array 1110 may collect red light, green light, and blue light. In one example, the plurality of pixels may collect Cyan light, Magenta light, Yellow light, and White light. Each of the pixels may include a photoelectric conversion device. The photoelectric conversion device may absorb light to generate charge carriers (electrons or holes). For example, the photoelectric conversion device may include photodiodes, phototransistors, photogates, pinned photodiodes, or combinations thereof. The output voltage of the plurality of pixels may be determined based on the generated charge carriers.

The pixel array 1110 may include a pixel group PXG. The pixel group PXG may be a set of pixels PX sharing: (i) a reset transistor RX, (ii) a selection transistor SX, and (iii) a source follower transistor DX. While it is shown that the pixel group PXG consists of four pixels PX, this is merely exemplary. In other examples, the pixel group PXG may include fewer or more than four pixels PX.

The pixel array 1110 may receive multiple driving signals such as row selection signals, reset signals, and charge transfer signals from the row driver 1120 to be operated. The row driver 1120 may provide multiple driving signals to the pixel array 1110 for driving multiple pixels. In an example, the driving signals may be provided on a row-by-row basis to the pixel array 1110. Pixels belonging to one row of the pixel array 1110 selected by the driving signal of the row driver 1120 may be simultaneously activated by the signal output from the row driver 1120. Pixels in the selected row may provide output voltages corresponding to the absorbed light to the output lines of the corresponding columns. In one example, pixels may provide output voltages one row at a time. The output voltages may be provided to a correlated double sampler 1142.

The pixel signal processing unit 1140 may include a correlated double sampler (CDS, 1142), an analog-to-digital converter (ADC, 1144), and a buffer 1146, as shown by FIG. 1. The correlated double sampler 1142 may sample and hold the output voltages provided by the pixel array 1110. The correlated double sampler 1142 may reduce noise and improve the Signal Noise Ratio (SNR). The correlated double sampler 1142 may be configured to remove noise voltage from the output voltage of the pixels. For example, the correlated double sampler 1142 may sample both the specific noise level and the signal level caused by the output signals, to output a difference level corresponding to the difference between the noise level and the signal level. The correlated double sampler 1142 may receive ramp signals generated by the ramp signal generator 1148 and output a comparison result by comparing them.

The analog-to-digital converter 1144 may convert the analog signal corresponding to the difference level received from the correlated double sampler 1142 into a digital signal. The buffer 1146 may latch the digital signal, and the latched signal may be sequentially output to the outside of the image sensor 1100 to be delivered to the image processor (not shown). The controller 1130 may control the row driver 1120 so that the pixel array 1110 may absorb light to accumulate charge carriers, temporarily store the accumulated charges, and output electrical signals corresponding to the stored charges to the outside of the pixel array 1110. Furthermore, the controller 1130 may control the pixel signal processing unit 1140 to measure the output voltages provided by the pixel array 1110.

Referring to FIG. 3, each of the plurality of pixels PX may include a photoelectric conversion element PD, a transfer transistor TX, and a floating diffusion region FD. The photoelectric conversion element PD may generate and accumulate photoelectric charges proportional to the amount of light incident from the outside, and may include a photodiode, phototransistor, photogate, pinned photodiode, or a combination thereof. The transfer transistor TX may include a transfer gate TG. The transfer gate TG may transmit charge carriers generated in the photodiode to the floating diffusion region FD for temporary storage. A transfer control voltage provided from a row driver 1120 may be applied to the transfer gate TG. For example, a channel may be formed between the photoelectric conversion element PD and the floating diffusion region FD by the transfer control voltage applied to the transfer gate. The charge carriers generated in the photoelectric conversion element PD may move to the floating diffusion region FD along the channel between the photoelectric conversion element PD and the floating diffusion region FD. The drain terminal of the transfer transistor TX may be electrically connected to the floating diffusion region FD, and the source terminal may be electrically connected to the photoelectric conversion element PD.

The floating diffusion region FD may accumulate and store the charges transferred from the photoelectric conversion element PD. The source follower transistor DX may be controlled based on the amount of charge accumulated in the floating diffusion region FD. The gate terminal of the source follower transistor DX may be electrically connected to the floating diffusion region FD, and a second power supply voltage VDD2 may be applied to the drain terminal, and the source terminal may be electrically connected to the drain terminal of the selection transistor SX. The source follower transistor DX may be a source follower buffer amplifier outputting a current proportional to the charge amount in the floating diffusion region FD.

The reset transistor RX may periodically reset the charges accumulated in the floating diffusion region FD. The gate terminal of the reset transistor RX may be electrically connected to a reset signal line RG. The drain terminal of the reset transistor RX may be connected to the floating diffusion region FD and the source terminal may be connected to the first power supply voltage VDD1. In one embodiment, the first power supply voltage VDD1 may be the same as the second power supply voltage VDD2. When the reset transistor RX is turned on, the first power supply voltage VDD1 connected to the source terminal is delivered to the floating diffusion region FD. When the reset transistor RX is turned on, the charges accumulated in the floating diffusion region FD may be discharged and the floating diffusion region FD may be reset. When the charge carrier is an electron, the voltage of the floating diffusion region FD may be lowered as electrons accumulate in the floating diffusion region FD. When the reset transistor RX is turned on, the electrons in the floating diffusion region FD may be discharged externally, and the voltage of the floating diffusion region FD may rise to the first power supply voltage VDD1. As the first power voltage VDD1 is applied to the floating diffusion region FD, the first power voltage VDD1 may be applied to the gate terminal of the source follower transistor DX to reset the output of the source follower transistor DX.

The selection transistor SX may select a plurality of pixels PX for each row. The selection transistor SX may transfer the current generated in the source follower transistor DX included in each of the selected pixels to an output line (not shown). The drain terminal, source terminal, and gate terminal of the select transistor SX may be electrically connected to the source terminal, output line, and row select line SG of the source follower transistor DX, respectively. A selection control signal from the row selection line SG may be applied to the gate terminal of the selection transistor SX, so that the signal generated by the source follower transistor DX may be output to the output line.

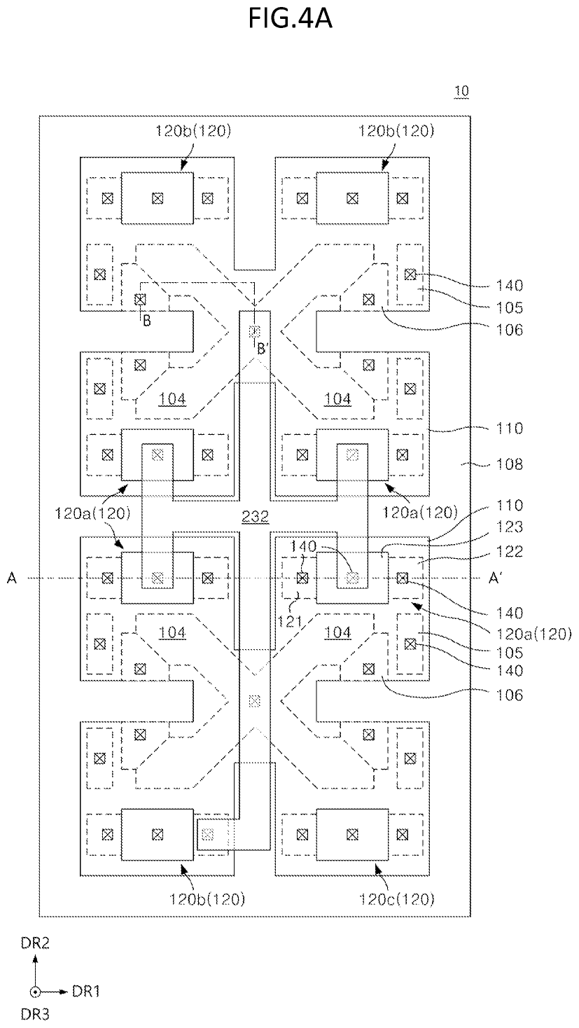

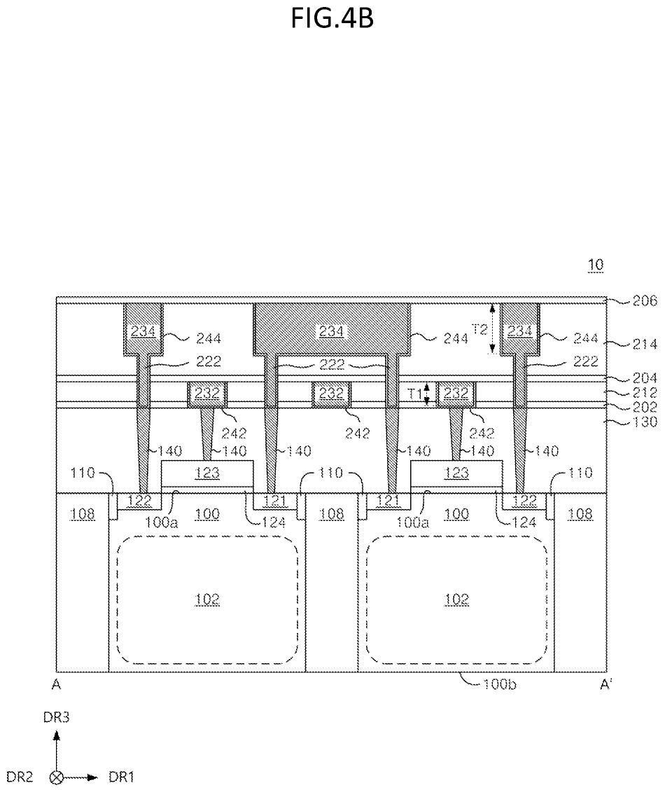

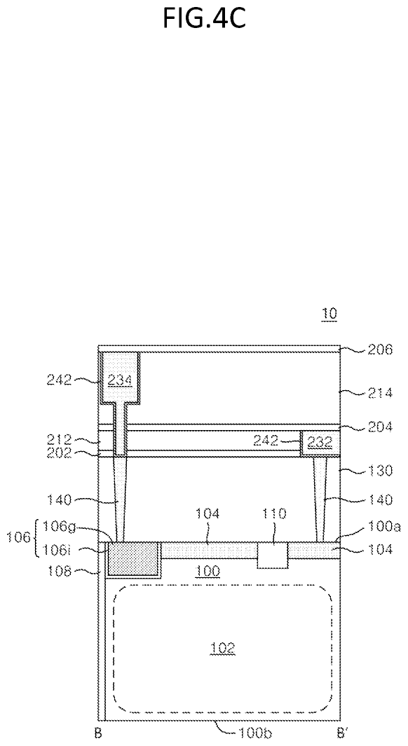

FIG. 4A represents a plan view of an image sensor according to exemplary embodiments; FIG. 4B is a cross-sectional view along line A-A′ of FIG. 4A; and FIG. 4C is a cross-sectional view along line B-B′ of FIG. 4A. For brevity of explanation, the second horizontal conductive line is not shown in FIG. 4A. Referring to FIGS. 4A and 4B, a substrate region 100 may be provided. The substrate region 100 may include semiconductor material, such as silicon (Si), germanium (Ge), or silicon-germanium (SiGe). For example, the substrate region 100 may refer to a region of a semiconductor substrate surrounded by a device isolation layer 110. The substrate region 100 may include a first surface 100a and a second surface 100b facing in opposite directions. The first surface 100a and the second surface 100b may extend along the first direction DR1 and the second direction DR2. The first surface 100a and the second surface 100b may be spaced apart from each other along the third direction DR3. The third direction DR3 may be perpendicular to the first direction DR1 and the second direction DR2. The substrate region 100 may have a first conductivity type. For example, the first conductivity type may be p-type or n-type. When the conductivity type is p-type, the substrate region 100 may be a silicon (Si) substrate containing a group 3 element (e.g., boron (B), aluminum (Al), gallium (Ga), indium (In)) or a group 2 element as impurities. Hereinafter, the region where the conductivity type is p-type may contain impurities containing a group 2 or 3 element. When the conductivity type is n-type, it may be a silicon (Si) substrate containing a group 5 element (e.g., phosphorus (P), arsenic (As), antimony (Sb)), group 6, or group 7 elements as impurities. Hereinafter, the region where the conductivity type is n-type may include impurities of group 5, 6, or 7 elements. Hereinafter, impurities that cause the substrate region 100 to have a first conductivity type and a second conductivity type may be referred to as first impurities and second impurities, respectively. When the first conductivity type is p-type or n-type, the second conductivity type may be n-type or p-type, respectively. The substrate region 100 may be an epi layer formed through an epitaxial growth process. For brevity of explanation, hereinafter the first conductivity type is described as p-type, and the second conductivity type is described as n-type.

A device isolation layer 110 may be provided on the substrate region 100. The device isolation layer 110 may define active regions. The active regions may be regions where a transfer gate structure 106, floating diffusion region 104, and ground region 105 are provided. The first surface 100a may refer to the upper surface of the active region. In a plan view, the device isolation layer 110 may surround the active region. The device isolation layer 110 may have a thickness along the third direction DR3. The thickness of the device isolation layer 110 may be smaller than the thickness of a pixel isolation layer 108. For example, the device isolation layer 110 may be a Shallow Trench Isolation (STI) layer. In one example, the upper surface of the device isolation layer 110 may be substantially at the same level as the first surface 100a. The device isolation layer 110 may include silicon nitride, silicon oxide, silicon oxynitride, or a combination thereof.

A pixel separation layer 108 may be provided on a lateral surface of the substrate region 100. In a plan view, the pixel separation layer 108 may enclose the substrate region 100. The pixel separation layer 108 may extend in a third direction DR3. In one example, the top and bottom surfaces of the pixel separation layer 108 may be substantially at the same level as the first surface 100a and the second surface 100b, respectively. The pixel separation layer 108 may prevent or reduce electrical crosstalk phenomena that degrade the signal-to-noise ratio due to charge carrier exchange between adjacent pixels. For example, the pixel separator 108 may include a conductive material (e.g., at least one of doped polysilicon, metal, metal silicide, metal nitride, or metal-containing material), an insulating material (e.g., silicon-based insulating materials (e.g., silicon nitride, silicon oxide, and/or silicon oxynitride)), or a high dielectric material (e.g., at least one metal selected from the group consisting of hafnium (Hf), zirconium (Zr), aluminum (Al), tantalum (Ta), titanium (Ti), yttrium (Y), and lanthanoid (La) metal oxide containing). In one example, the sidewalls of the pixel separation layer 108 may be doped with a highly reflective material to prevent or reduce optical crosstalk phenomena in adjacent pixels that are not illuminated. For example, the highly reflective material may be boron (Boron). When the pixel separation layer 108 includes a conductive material, in one example, a negative fixed charge layer may be provided between the pixel separation layer 108 and the substrate region 100. The negative fixed charge layer may include at least one metal selected from a group comprising hafnium (Hf), zirconium (Zr), aluminum (Al), tantalum (Ta), titanium (Ti), yttrium (Y), and lanthanides (La). However, the structure of the pixel separation layer 108 may be determined as needed. In one embodiment, the pixel separation layer 108 may be a single insulating layer. In another embodiment, the pixel separation layer 108 may include an upper insulating layer adjacent to the first surface 100a and a lower insulating layer adjacent to the second surface 100b.

A photoelectric conversion region 102 may be provided in the substrate region 100. In one embodiment, the photoelectric conversion region 102 may include at least one photodiode. For example, the photoelectric conversion region 102 may include a P-N junction photodiode. In one example, the p-type region may be the substrate region 100, and the n-type region may be formed by injecting the second impurity into the substrate region 100. In one example, the p-type region may be formed by injecting the first impurity into the substrate region 100. In this case, the doping concentration of the p-type region may be higher than the doping concentration of the substrate region 100. In one example, a plurality of P-N junctions located at different depths may be formed by injecting more of the first impurity into the substrate region 100. However, the inclusion of photodiodes in the photoelectric conversion region 102 is exemplary. In one embodiment, the photoelectric conversion region 102 may include phototransistors, photogates, or pinned photodiodes. When light is incident upon the photoelectric conversion region 102, electron-hole pairs (EHP) may be generated. For example, electron-hole pairs may be generated in the depletion region adjacent to the P-N junction. Since light may penetrate the substrate region 100 to different depths depending on its wavelength, different wavelengths of light may be efficiently detected by using a plurality of P-N junctions located at different depths. The stronger the intensity of light incident on the photoelectric conversion region 102, the more electron-hole pairs may be generated. When a reverse bias is applied to the photoelectric conversion region 102, charge carriers (either electrons or holes) may accumulate in the photoelectric conversion region 102. The accumulated charge carriers in the photoelectric conversion region 102 may move to a floating diffusion region 104 by a voltage applied to a transfer gate electrode 106g. The photoelectric conversion region 102 may be spaced apart from the floating diffusion region 104.

A floating diffusion region 104 may be provided on top of a substrate region 100. The floating diffusion region 104 may have the second conductivity type. In one embodiment, the floating diffusion region 104 may be formed by injecting the second impurity into the substrate region 100. The floating diffusion region 104 may be separated from a photoelectric conversion region 102. The region between the floating diffusion region 104 and the photoelectric conversion region 102 (i.e., a region of the substrate region 100) may have the first conductivity type. The floating diffusion region 104 may accumulate charge carriers provided from the photoelectric conversion region 102.

A transfer gate structure 106 may be provided adjacent to the floating diffusion region 104 and the photoelectric conversion region 102. The transfer gate structure 106 may be inserted into the substrate region 100. In another example, a part of the transfer gate structure 106 may protrude above a first surface 100a, and another part may be inserted into the substrate region 100. The transfer gate structure 106 may extend along a third direction DR3. The transfer gate structure 106 may be referred to as a vertical transfer gate (VTG). The transfer gate structure 106 may include a transfer gate electrode 106g and a transfer gate insulating layer 106i.

The transfer gate electrode 106g may be spaced apart from the substrate region 100. The transfer gate electrode 106g may extend along the third direction DR3. The transfer gate electrode 106g may comprise electrically conductive material. For example, the transfer gate electrode 106g may include doped polysilicon or metals (such as copper (Cu), aluminum (Al), molybdenum (Mo), platinum (Pt), titanium (Ti), tantalum (Ta), tungsten (W), or combinations thereof).

The transfer gate insulating layer 106i may be provided between the transfer gate electrode 106g and the substrate region 100. The transfer gate insulating layer 106i may extend along the surface of the transfer gate electrode 106g. The transfer gate insulating layer 106i may be configured to electrically isolate the transfer gate electrode 106g and the substrate region 100. For example, the transfer gate insulating layer 106i may include silicon-based insulating materials (such as silicon nitride, silicon dioxide, and/or silicon oxynitride) or high-k materials (such as metals oxides containing at least one metal selected from a group consisting of hafnium (Hf), zirconium (Zr), aluminum (Al), tantalum (Ta), titanium (Ti), yttrium (Y), and lanthanides (La)).

The transfer gate structure 106, photoelectric conversion region 102, and floating diffusion region 104 may form a transfer transistor. The transfer gate structure 106, photoelectric conversion region 102, and floating diffusion region 104 may form the gate, source, and drain of the transfer transistor, respectively. When a voltage is applied to the transfer gate electrode 106g, a channel of the second conductivity type may be formed in the region adjacent to the transfer gate structure 106 in the substrate region 100. The channel may be configured to move charge carriers generated in the photoelectric conversion region 102 to the floating diffusion region 104. When no voltage is applied to the transfer gate electrode 106g, the charge carriers generated in the photoelectric conversion region 102 may accumulate in the photoelectric conversion region 102.

A ground region 105 may be provided on the upper portion of the substrate region 100. The ground region 105 may have the second conductivity type. The ground region 105 may be formed by injecting the second impurity into the substrate region 100. The ground region 105 may be spaced apart from the photoelectric conversion region 102. The ground region 105 may be configured to apply a ground voltage to the substrate region 100.

A pixel transistor 120 may be adjacently provided on the first surface 100a of the substrate region 100. The pixel transistor 120 may be one of the transistors used in the circuitry required for image sensor operation. For example, the pixel transistor 120 may be a source follower transistor 120a, a reset transistor 120b, or a selection transistor 120c. The pixel transistor 120 may include a first source/drain region 121, a second source/drain region 122, a gate electrode 123, and a gate insulating layer 124.

The first source/drain region 121 and the second source/drain region 122 may be provided on the upper portion of the substrate region 100. When viewed along the third direction DR3, the first source/drain region 121 and the second source/drain region 122 may be spaced apart from each other with the gate electrode 123 interposed therebetween. Although the first source/drain region 121 and the second source/drain region 122 are shown to be spaced apart from each other along the first direction DR1, this is just an example. The separation direction of the first source/drain region 121 and the second source/drain region 122 may be determined according to the shape of the pixel transistor 120. The first source/drain region 121 and the second source/drain region 122 may have the second conductivity type.

The gate electrode 123 may be provided on the first surface 100a of the substrate region 100. The gate electrode 123 may include an electrically conductive material. For example, the gate electrode 123 may include doped polysilicon or metal (e.g., copper (Cu), aluminum (Al), molybdenum (Mo), platinum (Pt), titanium (Ti), tantalum (Ta), tungsten (W), or combinations thereof). The pixel transistor 120 in FIG. 4B may be a source follower transistor 120a. The gate electrode 123 may be electrically connected to a floating diffusion region 104. The voltage caused by the charge accumulation in the floating diffusion region may be the gate voltage. When the pixel transistor 120 is the reset transistor 120b, a reset signal voltage may be applied to the gate electrode 123 to apply an initial voltage to the floating diffusion region 104. Applying an initial voltage to the floating diffusion region 104 may be referred to as a reset operation. When the pixel transistor 120 is the selection transistor 120c, a selection signal voltage is applied to the gate electrode 123 to output a signal. A channel of the pixel transistor 120 may be formed between the first source/drain region 121 and the second source/drain region 122 by the voltage applied to the gate electrode 123.

The gate insulating layer 124 may be provided between the gate electrode 123 and the first surface 100a. The gate insulating layer 124 may include an electrically insulating material. For example, the gate insulating layer 124 may include silicon oxide, silicon nitride, or silicon oxynitride.

An upper insulating layer 130 may be provided on the substrate region 100 and the pixel isolation layer 108. The upper insulating layer 130 may cover various regions formed on the substrate region 100 and the gate electrode 123. The upper insulating layer 130 may include an electrically insulating material. For example, the upper insulating layer 130 may include silicon nitride, silicon oxide, silicon oxynitride, or combinations thereof.

Contacts 140 may be provided that penetrate the upper insulating layer 130. The contacts 140 may extend along a third direction DR3. The top surface of the contacts 140 may be located at substantially the same depth as the top surface of the upper insulating layer 130. The contacts 140 may be electrically connected to various regions and electrodes formed in the substrate region 100. For example, the contacts 140 may directly contact the gate electrode 123, the first source/drain region 121, and the second source/drain region 122, respectively. The contacts 140 may comprise an electrically conductive material. For example, the contacts 140 may include doped polysilicon or metals (e.g., copper (Cu), aluminum (Al), molybdenum (Mo), platinum (Pt), titanium (Ti), tantalum (Ta), tungsten (W), or combinations thereof).

A first horizontal conductive line 232 may be provided on the upper insulating layer 130. The first horizontal conductive line 232 may electrically connect the gate terminal of the source follower transistor 120a, the floating diffusion region 104, and the drain terminal of the reset transistor 120b. As the floating diffusion region 104 and the gate terminal of the source follower transistor are electrically connected by the first horizontal conductive line 232, the source follower transistor may be configured to be controlled according to the amount of charge accumulated in the floating diffusion regions 104. As the floating diffusion region 104 and the drain terminal of the reset transistor 120b are electrically connected by the first horizontal conductive line 232, the reset transistor 120b may be configured to periodically reset charges accumulated in the floating diffusion region 104. The first horizontal conductive line 232 may extend in a direction parallel to the first surface 100a. For example, the first horizontal conductive line 232 may extend along the first direction DR1 and the second direction DR2. The first horizontal conductive line 232 may have a first thickness T1. The first thickness T1 may be smaller than a second thickness T2 of the second horizontal conductive line 234, which will be described later. For example, the first thickness T1 may be 50% or less of the second thickness T2. As the first thickness T1 becomes smaller, the capacitance of the first horizontal conductive line 232 may become smaller. The first horizontal conductive line 232 may comprise an electrically conductive material. For example, the first horizontal conductive line 232 may include doped polysilicon or metals (e.g., copper (Cu), aluminum (Al), molybdenum (Mo), platinum (Pt), titanium (Ti), tantalum (Ta), tungsten (W), or combinations thereof).

A first capping layer 202 may be provided on the upper insulating layer 130. The first capping layer 202 may serve as an etch stop layer for the etching process performed on the layer above the first capping layer 202. For example, the first capping layer 202 may include silicon carbonitride (e.g., SiCN).

A first interlayer insulating layer 212 may be provided on the first capping layer 202. The first interlayer insulating layer 212 may include electrically insulating material. For example, the first interlayer insulating layer 212 may include silicon nitride, silicon oxide, silicon oxynitride, or combinations thereof. The first capping layer 202 and the first interlayer insulating layer 212 may surround the sides of the first horizontal conductive line 232.

A first diffusion barrier layer 242 may be provided on the sides and bottom surface of the first horizontal conductive line 232. The first diffusion barrier layer 242 may be disposed between the first capping layer 202, the first interlayer insulating layer 212, the upper insulating layer 130, and the contacts 140 and the first horizontal conductive line 232. The first diffusion barrier layer 242 may prevent the electrically conductive material (e.g., copper (Cu)) included in the first horizontal conductive line 232 from diffusing into other layers. For example, the first diffusion barrier layer 242 may include titanium, titanium nitride, tantalum, tantalum nitride, or combinations thereof. The first horizontal conductive line 232 and the first diffusion barrier layer 242 may be electrically connected to the gate electrode 123 of the source follower transistor through the contacts 140.

A second capping layer 204 and a second interlayer insulating layer 214 may be sequentially provided on the first interlayer insulating layer 212. The second capping layer 204 may serve as an etch stop layer for an etching process performed on the layer on the second capping layer 204. For example, the second capping layer 204 may include silicon carbonitride (e.g., SiCN). The second interlayer insulating layer 214 may include electrical insulating material. For example, the second interlayer insulating layer 214 may include silicon nitride, silicon oxide, silicon oxynitride, or a combination thereof.

A second horizontal conductive line 234 may be provided within the second interlayer insulating layer 214. The second horizontal conductive line 234 may be configured to transmit high-speed signals. For example, various driving signals such as row select signals, reset signals, and charge transfer signals may be transmitted through the second horizontal conductive line 234. The second horizontal conductive line 234 may extend in a direction parallel to the first surface 100a. For example, the second horizontal conductive line 234 may extend along the first direction DR1 and the second direction DR2. The second horizontal conductive line 234 may have a second thickness T2. When the second thickness is small, the resistance of the second horizontal conductive line 234 may be high. As the resistance of the second horizontal conductive line 234 increases, high-speed signal transmission characteristics may deteriorate. Accordingly, transmission of the driving signal through the second horizontal conductive line 234 may not be smooth. The second thickness T2 may be configured to be larger than the first thickness to ensure smooth transmission of driving signals by lowering overall resistance. For example, the second thickness T2 may be at least twice the first thickness T1. The second horizontal conductive line 234 may include electrically conductive material. For example, it may include doped polysilicon or metals (e.g., copper (Cu), aluminum (Al), molybdenum (Mo), platinum (Pt), titanium (Ti), tantalum (Ta), tungsten (W), or a combination thereof).

A via 222 may be provided on the bottom surface of the second horizontal conductive line 234. The via 222 may directly contact the bottom surface of the second horizontal conductive line 234. In one example, via 222 may be connected to second horizontal conductive line 234 without an interface therebetween. The via 222 may protrude from the bottom surface of the second horizontal conductive line 234. The via 222 may extend in the third direction DR3. The via 222 may be configured to sequentially penetrate the second interlayer insulating layer 214, the second capping layer 204, the first interlayer insulating layer 212, and the first capping layer 202. The via 222 may include electrically conductive material. For example, the via 222 may include doped polysilicon or metals (e.g., copper (Cu), aluminum (Al), molybdenum (Mo), platinum (Pt), titanium (Ti), tantalum (Ta), tungsten (W), or a combination thereof).

A second diffusion barrier layer 244 may be provided on the side and bottom surfaces of the second horizontal conductive line 234 and the via 222. The second diffusion barrier layer 244 may be interposed between the first capping layer 202, the first interlayer insulating layer 212, the second capping layer 204, the second interlayer insulating layer 214, and the contact 140 and the second horizontal conductive line 234 and the via 222. The second diffusion barrier layer 244 may prevent the electrically conductive material included in the second horizontal conductive line 234 and the via 222 (e.g., copper (Cu)) from diffusing into other layers. For example, the second diffusion barrier layer 244 may include titanium, titanium nitride, tantalum, tantalum nitride, or a combination thereof. The second horizontal conductive line 234, the via 222, and the second diffusion barrier layer 244 may be electrically connected to various regions formed on the substrate region 100 through the contact 140.

A third capping layer 206 may be provided on the second interlayer insulating layer 214. The third capping layer 206 may serve as an etch stop layer for the etching process performed on the layer formed on the third capping layer 206. For example, the third capping layer 206 may include silicon carbonitride (SiCN).

The first thickness T1 of the first horizontal conductive line 232 may be smaller than the second thickness T2 of the second horizontal conductive line 234 positioned at a higher location (for example, positioned in the second interlayer insulating layer 214). The first horizontal conductive line 232 may not transmit high-speed signals unlike the second horizontal conductive line 234. Accordingly, conductive lines transmitting high-speed signals (for example, the second horizontal conductive line 234) may have improved high-speed signal transmission characteristics, and the capacitance between conductive lines not transmitting high-speed signals (for example, the first horizontal conductive line 232) and other conductive lines (for example, vias 222) may be low in the image sensor 10.

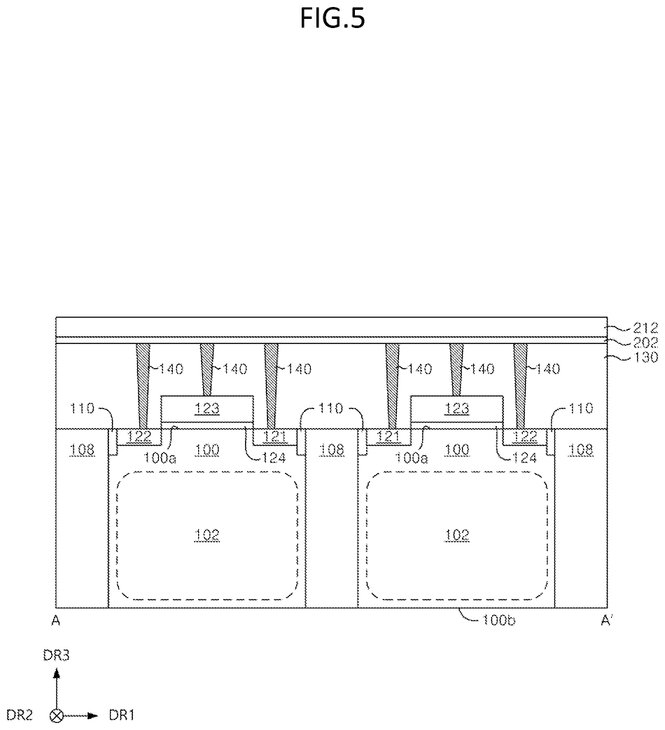

FIGS. 5 to 11 correspond to line A-A′ in FIG. 4A and describe the manufacturing methods of an image sensor according to exemplary embodiments. For brevity of explanation, content that is substantially the same as that described with reference to FIGS. 4A to 4C may not be described. Referring to FIG. 5, a first capping layer 202 and a first interlayer insulating layer 212 may be sequentially stacked on the device layer (DL). The device layer (DL) may include a substrate region 100, a device separation layer 110, a pixel separation layer 108, a photoelectric conversion region 102, a floating diffusion region 104, a transfer gate structure 106, a ground region 105, a pixel transistor 120, an upper insulating layer 130, and contacts 140. The first capping layer 202 and the first interlayer insulating layer 212 may be formed on the device layer (DL) by a deposition process (e.g., chemical vapor deposition (CVD), physical vapor deposition (PVD), or atomic layer deposition (ALD)). The first capping layer 202 may protect layers under the first capping layer 202 from damage. The first capping layer 202 may serve as an etch stop layer for the etching process performed on the first interlayer insulating layer 212. For example, the first capping layer 202 may include silicon carbonitride (SiCN). The first interlayer insulating layer 212 may include an electric insulating material. For example, it may include silicon nitride, silicon oxide, silicon oxynitride, or combinations thereof.

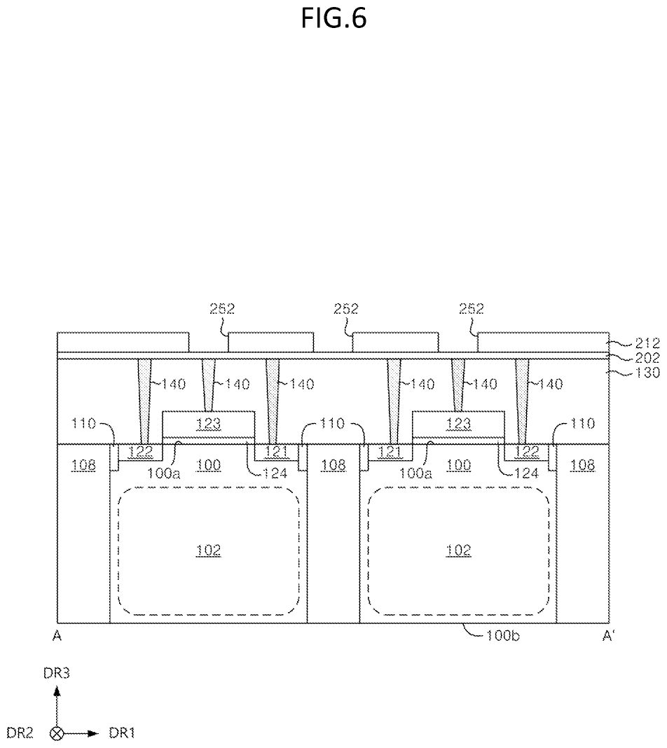

Referring to FIG. 6, the first interlayer insulating layer 212 may be patterned. For example, an etching process may be performed on the first interlayer insulating layer 212 using a photoresist pattern provided on the first interlayer insulating layer 212 as an etch mask. The etching process on the first interlayer insulating layer 212 may performed until the first capping layer 202 is exposed. The photoresist pattern may be removed during or after the etching process. The region of the first interlayer insulating layer 212 that is etched may be referred to as the first trench 252. The first trench 252 may expose the first capping layer 202. The first trench 252 may have a first depth D1. The first depth D1 may be the size of the first trench 252 following the third direction DR3. The first depth D1 may be shallower than the second depth D2 of the second trench 254, which will be described later. The first thickness of the first horizontal conductive line 232 formed in the first trench 252 may be smaller than the second thickness of the second horizontal conductive line 234 formed in the second trench 254. Accordingly, the capacitance between the first horizontal conductive line 232 and other conductive lines may be configured to be relatively low.

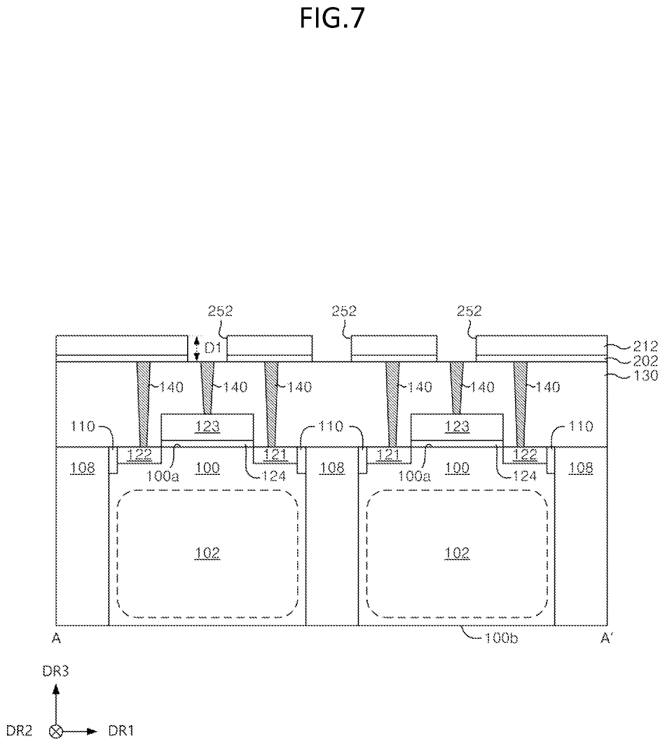

Referring to FIG. 7, the first capping layer 202 exposed by the first trench 252 may be removed. For example, the first capping layer 202 exposed by the first trench 252 may be selectively removed by an etching process utilizing an etchant with a high etch selectivity for the first capping layer 202. The first trench 252 may extend to the region where the first capping layer 202 is removed. The first trench 252 may expose the upper insulating layer 130 and the contact 140.

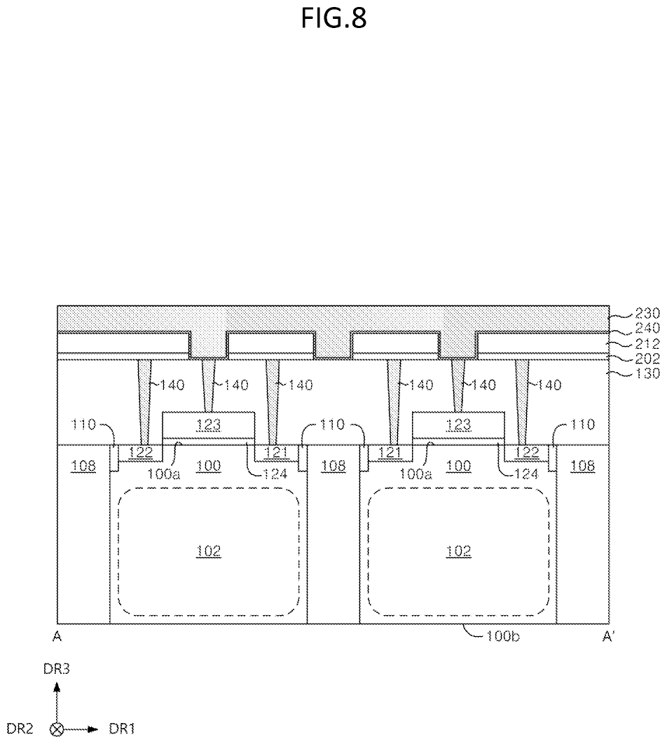

Referring to FIG. 8, on top of the first interlayer insulating layer 212, a preliminary diffusion preliminary diffusion barrier layer 240 and a conductive material layer 230 may be sequentially stacked. In one example, the preliminary diffusion preliminary diffusion barrier layer 240 may be formed on the first interlayer insulating layer 212 by a deposition process such as Chemical Vapor Deposition (CVD), Physical Vapor Deposition (PVD), or Atomic Layer Deposition (ALD). For example, the preliminary diffusion preliminary diffusion barrier layer 240 may include titanium, titanium nitride, tantalum, tantalum nitride, or combinations thereof. The preliminary diffusion preliminary diffusion barrier layer 240 and the conductive material layer 230 may extend into the first trench 252. The preliminary diffusion preliminary diffusion barrier layer 240 may extend along the edge of the first trench 252.

The conductive material layer 230 may fill the remaining portion of the first trench 252 except for the region where the preliminary diffusion preliminary diffusion barrier layer 240 is placed. In one example, the conductive material layer 230 may be formed on the preliminary diffusion barrier layer 240 by an electroplating process using a seed layer provided on the preliminary diffusion barrier layer 240. In another example, the conductive material layer 230 may be formed by a deposition process, such as Chemical Vapor Deposition (CVD), Physical Vapor Deposition (PVD), or Atomic Layer Deposition (ALD). For example, the conductive material layer 230 may include doped polysilicon or metals like copper (Cu), aluminum (Al), molybdenum (Mo), platinum (Pt), titanium (Ti), tantalum (Ta), tungsten (W), or combinations thereof.

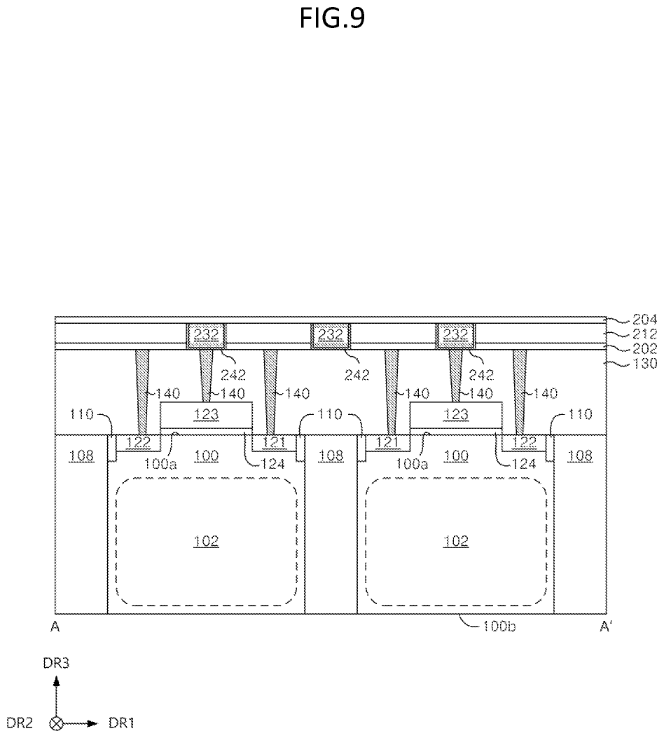

Referring to FIG. 9, a planarization process may be performed on the conductive material layer 230 and the preliminary diffusion preliminary diffusion barrier layer 240. For example, the planarization process may be a Chemical Mechanical Polishing process. The conductive material layer 230 and the preliminary diffusion barrier layer 240 on the first interlayer insulating layer 212 may be removed, and the conductive material layer 230 and the preliminary diffusion barrier layer 240 in the first trench 252 may remain. The conductive material layer 230 and the preliminary diffusion barrier layer 240 in the first trench 252 may be referred to as a first horizontal conductive line 232 and a first diffusion barrier layer 242, respectively.

A second capping layer 204 may be formed on the first interlayer insulating layer 212, the first horizontal conductive line 232, and the first diffusion barrier layer 242. In one example, the second capping layer 204 may be formed by a deposition process like Chemical Vapor Deposition (CVD), Physical Vapor Deposition (PVD), or Atomic Layer Deposition (ALD). The second capping layer 204 may protect layers under the second capping layer 204 from damage. The second capping layer 204 may be an etch stop layer for an etching process performed on the second interlayer insulating layer 214. For example, the second capping layer 204 may include aluminum oxide, aluminum nitride, silicon nitride, silicon carbide, silicon oxynitride, or silicon carbonitride.

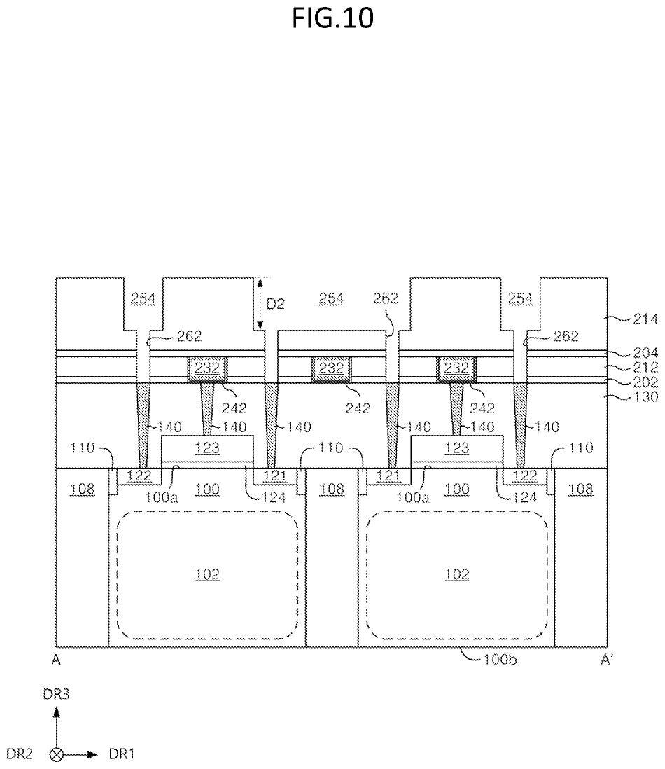

Referring to FIG. 10, similar to what is described with reference to FIGS. 5 to 7, after forming the second interlayer insulating layer 214 on the second capping layer 204, the second interlayer insulating layer 214, the second capping layer 204, the first interlayer insulating layer 212, and the first capping layer 202 may be patterned to form the second trench 254 and via holes 262. In one example, the second interlayer insulating layer 214 may be formed on the second capping layer 204 by a deposition process like Chemical Vapor Deposition (CVD), Physical Vapor Deposition (PVD), or Atomic Layer Deposition (ALD). The second interlayer insulating layer 214 may include electrical insulating materials. For example, the second interlayer insulating layer 214 may include silicon nitride, silicon oxide, silicon oxynitride, or combinations thereof.

The second trench 254 may be formed on the upper portion of the second interlayer insulating layer 214. The second trench 254 may extend in a direction parallel to the first surface 100a. For example, the second trench 254 may extend in the first direction DR1 and the second direction DR2. The second trench 254 may have a second depth D2. The second depth D2 may be the size of the second trench 254 along the third direction DR3. The second depth (D2) may be deeper than the first depth D1 of the first trench 252. Accordingly, the thickness of the second horizontal conductive line 234 formed in the second trench 254 may be greater than the thickness of the first horizontal conductive line 232 formed in the first trench 252. Therefore, the second horizontal conductive line 234 may be configured to have relatively low resistance.

The via hole 262 may extend in the third direction DR3. The via hole 262 may be formed to penetrate through the lower portion of the second interlayer insulating layer 214, the second capping layer 204, the first interlayer insulating layer 212, and the first capping layer 202. The via hole 262 may expose the contact 140. In one example, forming the second trench 254 and the via hole 262 in the second interlayer insulating layer 214 may include performing a dual damascene process.

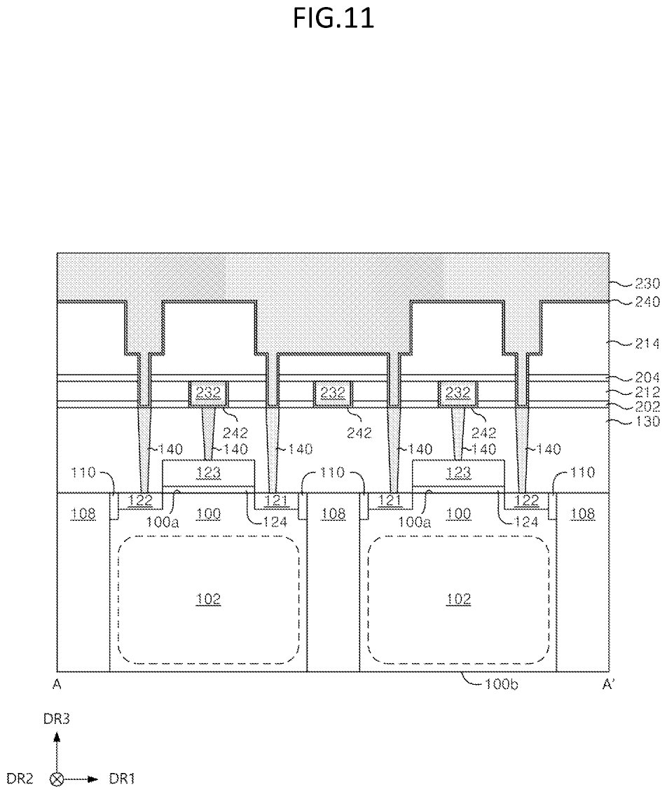

Referring to FIG. 11, a preliminary diffusion barrier layer 240 and a conductive material layer 230 may be sequentially stacked on the second interlayer insulating layer 214. In one example, the preliminary diffusion barrier layer 240 may be formed on the second interlayer insulating layer 214 by a deposition process (e.g., chemical vapor deposition (CVD), physical vapor deposition (PVD), or atomic layer deposition (ALD)). For example, the preliminary diffusion barrier layer 240 may include titanium, titanium nitride, tantalum, tantalum nitride, or a combination thereof. The preliminary diffusion barrier layer 240 and the conductive material layer 230 may extend into the second trench 254 and the via hole 262. The preliminary diffusion barrier layer 240 may extend along the edges of the second trench 254 and the via hole 262. The conductive material layer 230 may fill the remaining portion of the second trench 254 and the via hole 262 excluding the region where the preliminary diffusion barrier layer 240 is disposed. In one example, the conductive material layer 230 may be formed on the preliminary diffusion barrier layer 240 by an electroplating process using a seed layer provided on the preliminary diffusion barrier layer 240. In one example, the conductive material layer 230 may be formed on the preliminary diffusion barrier layer 240 by a deposition process (e.g., chemical vapor deposition (CVD), physical vapor deposition (PVD), or atomic layer deposition (ALD)). For example, the conductive material layer 230 may be doped polysilicon or metal (e.g., copper (Cu), aluminum (Al), molybdenum (Mo), platinum (Pt), titanium (Ti), tantalum. (Ta), tungsten (W), or a combination thereof).

Referring to FIG. 4B, a planarization process may be performed on the conductive material layer 230 and the preliminary diffusion barrier layer 240. For example, the planarization process may be a Chemical Mechanical Polishing process. The conductive material layer 230 and the preliminary diffusion barrier layer 240 on the second interlayer insulating layer 214 may be removed. The conductive material layer 230 and the preliminary diffusion barrier layer 240 may remain in the second trench 254 and the via hole 262. The conductive material layer 230 in the second trench 254 and via hole 262 may be referred to as a second horizontal conductive line 234 and a via 222, respectively. The preliminary diffusion barrier layer 240 in the second trench 254 and the via hole 262 may be referred to as a second diffusion barrier layer 244.

A third capping layer 206 may be formed on the second interlayer insulating layer 214, the second horizontal conductive line 234, and the second diffusion barrier layer 244. In one example, the third capping layer 206 may be formed by a deposition process (e.g., Chemical Vapor Deposition (CVD), Physical Vapor Deposition (PVD), or Atomic Layer Deposition (ALD)). The third capping layer 206 may protect layers under the third capping layer 206 from damage. For example, the second capping layer 204 may include aluminum oxide, aluminum nitride, silicon nitride, silicon carbide, silicon oxynitride, or silicon carbonitride.

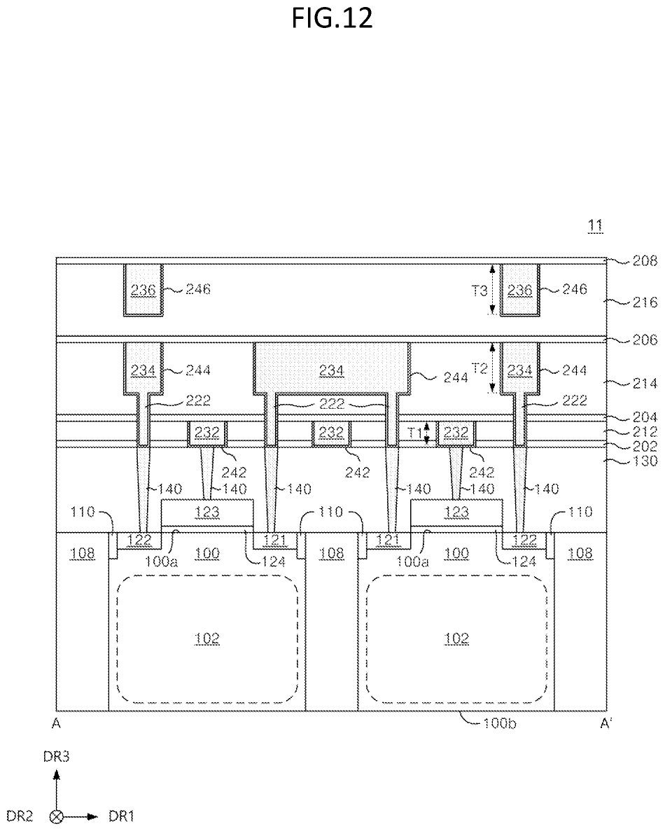

FIG. 12 is a cross-sectional view corresponding to the A-A′ line of FIG. 4A, representing an image sensor according to exemplary embodiments. For brevity of explanation, differences from what is described with reference to FIGS. 4A to 4C are explained. Referring to FIG. 12, unlike what is described with reference to FIGS. 4A to 4C, the image sensor 11 may include a third interlayer insulating layer 216 and a fourth capping layer 208 sequentially provided on the third capping layer 206. The third interlayer insulating layer 216 may include electrically insulating material. For example, the third interlayer insulating layer 216 may include silicon nitride, silicon oxide, silicon oxynitride, or a combination thereof.

A third horizontal conductive line 236 may be provided in the third interlayer insulating layer 216. The third horizontal conductive line 236 may be electrically connected to other conductive lines placed in different locations through vias and contacts (e.g., the first horizontal conductive line 232 or the second horizontal conductive line 234) or to various regions formed in the substrate region 100. The third horizontal conductive line 236 may be configured to transmit high-speed signals. For example, multiple driving signals such as row selection signals, reset signals, and charge transfer signals may be transmitted through the third horizontal conductive line 236. The third horizontal conductive line 236 may extend in a direction parallel to the first surface 100a. For example, the third horizontal conductive line 236 may extend along the first direction DR1 and the second direction DR2. The third horizontal conductive line 236 may have a third thickness T3. When the third thickness is small, the resistance of the third horizontal conductive line 236 may be high. As the resistance of the third horizontal conductive line 236 increases, the high-speed signal transmission characteristics deteriorate, and the driving signal may not be smoothly transmitted through the third horizontal conductive line 236. Therefore, the third thickness T3 may be configured to be greater than the first thickness T1 to allow smooth transmission of driving signals through the third horizontal conductive line 236. For example, the third thickness T3 may be more than twice the first thickness T1. For example, the third thickness T3 may be substantially the same as the second thickness T2. The third horizontal conductive line 236 may include electrically conductive material. For example, the third horizontal conductive line 236 may include doped polysilicon or metal (e.g., copper (Cu), aluminum (Al), molybdenum (Mo), platinum (Pt), titanium (Ti), tantalum (Ta), tungsten (W), or a combination thereof).

A third diffusion barrier layer 246 may be provided on the sides and bottom surface of the third horizontal conductive line 236. When a via is provided on the bottom surface of the third horizontal conductive line 236, the third diffusion barrier layer 246 may extend along the sides and bottom surface of the via. The third diffusion barrier layer 246 may be interposed between the third interlayer insulating layer 216 and the fourth capping layer 208 and the third horizontal conductive line 236. The third diffusion barrier layer 246 may prevent the electrically conductive material included in the third horizontal conductive line 236 (e.g., copper (Cu)) from diffusing to other layers. For example, the third diffusion barrier layer 246 may include titanium, titanium nitride, tantalum, tantalum nitride, or a combination thereof.

A fourth capping layer 208 may be provided on the third interlayer insulating layer 216. The fourth capping layer 208 may be an etch stop layer for an etching process performed on a layer formed on the fourth capping layer 208. For example, the fourth capping layer 208 may include silicon carbonitride (e.g., SiCN).

Thus, as described hereinabove, embodiments of the present invention may provide an image sensor 11 with improved high-speed signal transmission characteristics and small capacitance. For example, conductive lines that transmit high-speed signals (e.g., the second horizontal conductive line 234 and the third horizontal conductive line 236) may have improved high-speed signal transmission characteristics. For example, the capacitance between conductive lines that do not transmit high-speed signals (e.g., the first horizontal conductive lines 232) may be small.

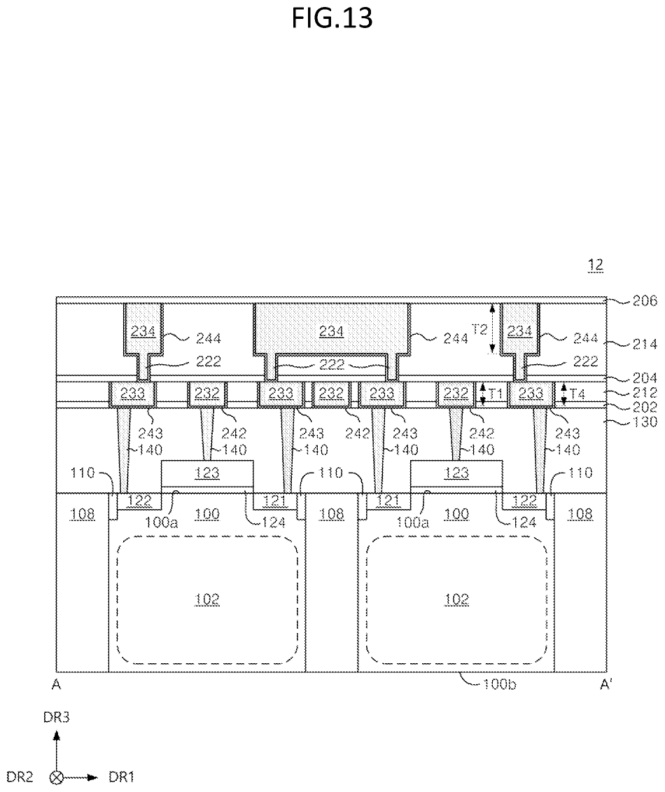

FIG. 13 is a cross-sectional view corresponding to line A-A′ of FIG. 4A, representing an image sensor according to exemplary embodiments. For brevity of explanation, differences from what is described with reference to FIGS. 4A to 4C are explained. Referring to FIG. 13, unlike what is described with reference to FIGS. 4A to 4C, the image sensor 12 may further include a pad 233 provided between the contact 140 and the second horizontal conductive line 234. The pad 233 may electrically connect the contact 140 and the second horizontal conductive line 234. The pad 233 may extend in a direction parallel to the first surface 100a. For example, the pad 233 may extend in a first direction DR1 and a second direction DR2. The pad 233 may be inserted in the first capping layer 202 and the first interlayer insulating layer 214. In one example, the pad 233 may be formed along with the first horizontal conductive line 232 during the process of forming the first horizontal conductive line 232. The pad 233 may be located at substantially the same height as the first horizontal conductive line 232. The pad 233 may have a fourth thickness T4. In one example, the fourth thickness T4 may be substantially the same as the first thickness T1 of the first horizontal conductive line 232. The fourth thickness T4 may be less than the second thickness T2 of the second horizontal conductive line 234. For example, the fourth thickness T4 may be 50% or less of the second thickness T2. As the fourth thickness T4 becomes smaller, the capacitance between the pad 233 and other conductive lines may decrease. For example, as the fourth thickness T4 is smaller, the capacitance between the pad 233 and the first horizontal conductive line 232 may be smaller. The pad 233 may comprise an electrically conductive material. For example, the pad 233 may include doped polysilicon or metal (for example, copper (Cu), aluminum (Al), molybdenum (Mo), platinum (Pt), titanium (Ti), tantalum (Ta), tungsten (W), or combinations thereof).

A pad diffusion barrier layer 243 may be provided on the side and bottom surfaces of the pad 233. The pad diffusion barrier layer 243 may be disposed between the first capping layer 202, the first interlayer insulating layer 212, the upper insulating layer 130, and the contact 140 and the pad 233. The pad diffusion barrier layer 243 may prevent the diffusion of the electrically conductive material included in the pad 233 (e.g., copper (Cu)) into other layers. For example, the pad diffusion barrier layer 243 may comprise titanium, titanium nitride, tantalum, tantalum nitride, or combinations thereof.

The present invention may provide an image sensor 12 with improved high-speed signal transmission characteristics and small capacitance. For example, conductive lines that transmit high-speed signals (e.g., the second horizontal conductive line 234 and the third horizontal conductive line 236) may have improved high-speed signal transmission characteristics. For example, the capacitance between conductive lines that do not transmit high-speed signals (e.g., the first horizontal conductive line 232 and the pad 233) may be small.

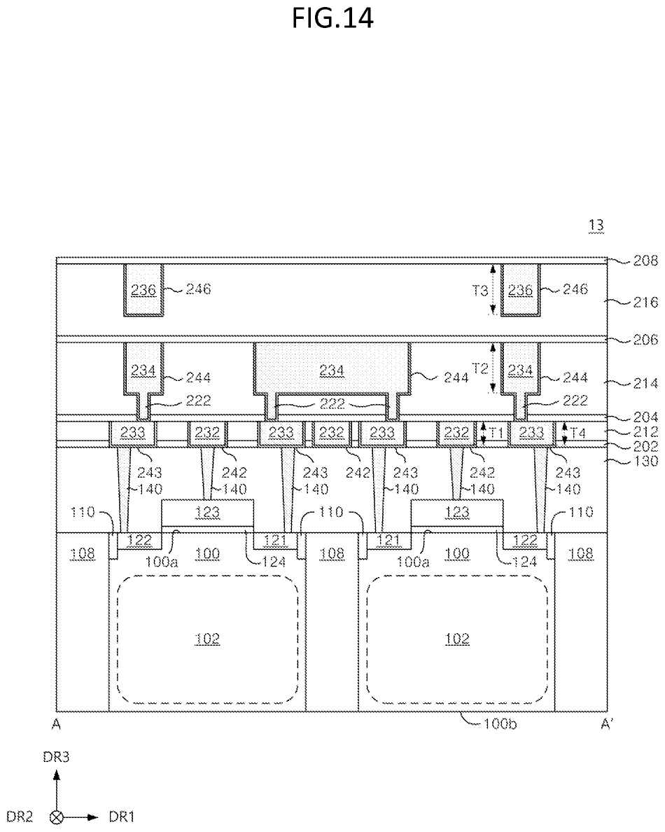

FIG. 14 is a cross-sectional view corresponding to line A-A′ of FIG. 4A, representing an image sensor according to exemplary embodiments. For brevity of explanation, differences from what is described with reference to FIG. 13 will be explained. Referring to FIG. 14, unlike what was described with reference to FIG. 13, the image sensor 13 may include a third interlayer insulating layer 216 and a fourth capping layer 208 provided sequentially on the third capping layer 206. The third interlayer insulating layer 216 may include an electrical insulating material. For example, the third interlayer insulating layer 216 may include silicon nitride, silicon oxide, silicon oxynitride, or combinations thereof. A third horizontal conductive line 236 may be provided in the third interlayer insulating layer 216. The third horizontal conductive line 236 may be electrically connected to conductive lines placed at other positions through vias and contacts (for example, the first horizontal conductive line 232 or the second horizontal conductive line 234) or various regions formed in the substrate region 100. The third horizontal conductive line 236 may be configured to transmit high-speed signals. For example, multiple driving signals like row selection signals, reset signals, and charge transfer signals may be transmitted through the third horizontal conductive line 236. The third horizontal conductive line 236 may extend in a direction parallel to the first surface 100a. For example, the third horizontal conductive line 236 may extend along the first direction DR1 and the second direction DR2. The third horizontal conductive line 236 may have a third thickness T3. When the third thickness is small, the resistance of the third horizontal conductive line 236 may be high. As the resistance of the third horizontal conductive line 236 increases, the high-speed signal transmission characteristics deteriorate, and the driving signal may not be smoothly transmitted through the third horizontal conductive line 236. Accordingly, the third thickness T3 may be larger than the first thickness T1 and the fourth thickness T4 so that the driving signal is smoothly transmitted through the third horizontal conductive line 236. For example, the third thickness T3 may be twice or more than at least one of the first thickness T1 and the fourth thickness T4. For example, the third thickness T3 may be substantially equal to the second thickness T2. The third horizontal conductive line 236 may include an electrically conductive material. For example, the third horizontal conductive line 236 may include doped polysilicon or metals (e.g., copper (Cu), aluminum (Al), molybdenum (Mo), platinum (Pt), titanium (Ti), tantalum (Ta), tungsten (W), or combinations thereof).

A third diffusion barrier layer 246 may be provided on the sides and bottom surface of the third horizontal conductive line 236. When a via is provided on the bottom surface of the third horizontal conductive line 236, the third diffusion barrier layer 246 may extend along the sides and bottom surface of the via. The third diffusion barrier layer 246 may be interposed between the third interlayer insulating layer 216 and the third horizontal conductive line 236 and between the fourth capping layer 208 and the third horizontal conductive line 236. The third diffusion barrier layer 246 may prevent the electrically conductive material included in the third horizontal conductive line 236 (e.g., copper (Cu)) from diffusing to other layers. For example, the third diffusion barrier layer 246 may include titanium, titanium nitride, tantalum, tantalum nitride, or combinations thereof.

A fourth capping layer 208 may be provided on the third interlayer insulating layer 216. The fourth capping layer 208 may function as an etching stop layer for etching processes performed on layers formed on the fourth capping layer 208. For example, the fourth capping layer 208 may include silicon carbonitride (e.g., SiCN).

The present invention may provide an image sensor 13 with improved high-speed signal transmission characteristics and small capacitance. For example, conductive lines that transmit high-speed signals (e.g., the second horizontal conductive line 234 and the third horizontal conductive line 236) may have improved high-speed signal transmission characteristics. For example, the capacitance between conductive lines that do not transmit high-speed signals (e.g., the first horizontal conductive line 232 and the pad 233) may be small.

According to the present disclosure, the present invention may provide an image sensor with reduced capacitance between conductive lines that do not transmit high-speed signals and other conductive lines. The present disclosure may provide an image sensor with improved high-speed signal transmission characteristics of a high-speed signal transmission conductive line.

According to the present disclosure, the present invention may provide a method of fabricating an image sensor with reduced capacitance between conductive lines that do not transmit high-speed signals and other conductive lines. The present disclosure may provide a method of fabricating an image sensor with improved high-speed signal transmission characteristics of a high-speed signal transmission conductive line.

While the present disclosure is described with reference to embodiments thereof, it will be apparent to those of ordinary skill in the art that various changes and modifications may be made thereto without departing from the spirit and scope of the present disclosure as set forth in the following claims.

What is claimed is:

1. An image sensor, comprising:
a substrate region including a photoelectric conversion region and a floating diffusion region therein, said floating diffusion region configured to receive charges generated in the photoelectric conversion region in response to light incident the photoelectric conversion region; and
first and second horizontal conductive lines extending on the substrate region, but at different heights relative to a surface of the substrate region, said first horizontal conductive line electrically connected to the floating diffusion region and having a thickness smaller than a thickness of the second horizontal conductive line.

2. The image sensor of claim 1, wherein the first horizontal conductive line extends closer to the substrate region than the second horizontal conductive line.

3. The image sensor of claim 1, further comprising:
a source follower transistor, which extends on the substrate region and has a gate terminal electrically connected to the first horizontal conductive line.

4. The image sensor of claim 1, further comprising:
a reset transistor provided, which extends on the substrate region and has a drain terminal electrically connected to the first horizontal conductive line.

5. The image sensor of claim 1, wherein a first thickness of the first horizontal conductive line is less than half a second thickness of the second horizontal conductive line.

6. The image sensor of claim 1, further comprising:
a plurality of contacts extending on the substrate region; and
a first via extending between the second horizontal conductive line and the substrate region;
wherein one of the plurality of contacts is electrically connected to the first horizontal conductive line; and
wherein another one of the plurality of contacts is electrically connected to the first via.

7. The image sensor of claim 6, wherein the first via overlaps the first horizontal conductive line along a direction parallel to the top surface of the substrate region.

8. The image sensor of claim 6, further comprising a second via, which extends on the second horizontal conductive line and has a shorter length relative to a length of the first via.

9. The image sensor of claim 8, further comprising a pad extending between the second via and another one of the plurality of contacts, which is electrically connected to the pad.

10. The image sensor of claim 9, wherein the pad has the same thickness as the first horizontal conductive line.

11. The image sensor of claim 9, wherein the pad overlaps the first horizontal conductive line along a direction parallel to the top surface of the substrate region.

12. The image sensor of claim 1, further comprising:
a third horizontal conductive line provided at a higher position than the first horizontal conductive line and the second horizontal conductive line relative to the surface of the substrate region, said third horizontal conductive line having a greater thickness than the first horizontal conductive line.

13. The image sensor of claim 12, wherein the third horizontal conductive line has the same thickness as the second horizontal conductive line.

14. The image sensor of claim 12, further comprising:
a second via extending on the second horizontal conductive line and having a longer length than the first via; and
a pad provided between the second via and another one of the plurality of contacts, and electrically connected to the another one of the plurality of contacts; and
wherein the third horizontal conductive line has a thickness greater than a thickness of the pad.

15. A method of fabricating image sensor, comprising:
forming a device layer including:
a substrate region having a photoelectric conversion region and a floating diffusion region therein, said floating diffusion region configured to receive charges generated in the photoelectric conversion region;
an upper insulating layer extending on the substrate region; and
a first contact that penetrates the upper insulating layer and is electrically connected to the floating diffusion region;
sequentially forming a first capping layer and a first interlayer insulating layer on the upper insulating layer;
forming a first trench exposing the first contact by etching the first interlayer insulating layer and the first capping layer;
forming a second interlayer insulating layer on the upper insulating layer; and
forming a second trench by etching the second interlayer insulating layer; and
wherein a first depth of the first trench is shallower than a second depth of the second trench, and the first trench and the second trench are formed at different heights relative to the substrate region.

16. The method of claim 15, wherein the first trench is formed closer to the substrate region than the second trench.

17. The method of claim 15, wherein the first depth is less than half the second depth.

18. The method of claim 15, wherein the device layer further comprises a source follower transistor provided between the substrate region and the upper insulating layer, and a second contact electrically connected to a gate electrode of the source follower transistor; and wherein the first trench is formed to expose the second contact.

19. The method of claim 15, wherein the device layer further comprises a reset transistor provided between the substrate region and the upper insulating layer and a third contact electrically connected to a drain electrode of the reset transistor; and wherein the first trench is formed to expose the third contact.

20. The method of claim 15, further comprising:
forming a second capping layer between the first interlayer insulating layer and the second interlayer insulating layer; and
forming a first via hole penetrating the second interlayer insulating layer, the second capping layer, the first interlayer insulating layer, and the first capping layer; and
wherein the device layer further comprises a fourth contact penetrating the upper insulating layer, the second trench is connected to the first via hole, and the first via hole exposes the fourth contact.
